(19) United States
(12) Patent Application Publication
(10) Pub. No.: US 2026/0186637 A1
(43) Pub. Date: Jul. 2, 2026

(54) FOCUSED TREE CONTROL

(71) Applicant: Hexagon Technology Center GmbH, Heerbrugg (CH)

(72) Inventor: Keith D. Harvey, Huntsville, AL (US)

(21) Appl. No.: 19/008,346

(22) Filed: Jan. 2, 2025

(51) Int. Cl. G06F 3/04842; G06F 9/451

(52) U.S. Cl. CPC G06F 3/04842; G06F 9/451

(57) ABSTRACT

Illustrative embodiments provide a specialized graphical user interface for accessing multiple levels of a tree structure while allowing the user to focus the view to a specific subsection of the tree without losing track of the user's location within the tree.

### FIELD

Illustrative embodiments of the invention generally relate to data tree structures and, more particularly, various embodiments of the invention relate to navigating data tree structures.

### BACKGROUND

Computer-aided engineering software typically presents an operator with a large menu of objects, which object may be selected and inserted into a 3D computer-aided design drawing by the operator.

The menu may take the form of a hierarchical tree in a graphical user interface, in which an object is shown by a graphical device (or “node”). Some such objects have subordinate objects. Selection of an object's node by an operator causes the node to expand to display nodes for the object's subordinate objects.

### SUMMARY OF VARIOUS EMBODIMENTS

In accordance with one embodiment of the invention, a method for navigating a large tree of nodes representing components of a computer-aided design drawing, the tree having a plurality of nodes across a plurality of levels, includes:
accessing data defining a hierarchical tree of nodes, each node representing a corresponding component of a capital project or a subcomponent of a component of a capital project;
presenting, via a first user interface displayed on a computer display, a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
receiving, via the first user interface, a first user selection of a particular node from the displayed nodes, said particular node being a first selected node, the first selected node being from the first level of nodes;
displaying, on the computer display in response to said first user selection of said first selected node, a second user interface separate from the first user interface, the second user interface displaying said first selected node in addition to first associated nodes that are associated nodes to the first selected node;
receiving, via the first user interface, a second user selection of a second particular node from the tree of nodes, said second particular node being a second selected node from the first level of nodes; and in response to said second selection; and
displaying, in the second user interface, said second selected node and a second set of sibling nodes of said second selected node while still displaying in the second user interface the first selected node in addition to a parent node of said first selected node, and the first associated nodes of said first selected node.

Some embodiments also include displaying, on the computer display, a selection pane, the selection pane displaying a section of the large tree of nodes, the section graphically identifying each node of a plurality of nodes selected by the user. In some such embodiments, graphically identifying each node of the plurality of nodes selected by the user includes: highlighting each node of the plurality of nodes selected by the user.

Some embodiments include providing a selection pane toggle device that, in a first state causes the selection pane to be displayed, and in an alternate, second state cause the selection pane to not be displayed.

Some embodiments include displaying, as part of the second user interface, a set of graphical elements graphically indicating to the user that the second user interface is distinct from the first user interface.

Some embodiments include: prior to receiving said first user selection of said first selected node: displaying a focus button in response to the user placing a graphical pointer over said particular node and, in response to user activation of said focus button: causing said generating of said second user interface.

In some such embodiments, wherein the first selected node depends from a parent node via a set of intervening nodes, the method further includes:
prior to receiving said first user selection of said first selected node:
displaying, adjacent to the focus button, a path window displaying the path from the first selected node to the parent node and all intervening nodes.

Some embodiments further include: displaying a back button configured to revert the user interface to a previous state after receiving said second user selection, said previous state displaying the user interface as it was prior to receiving said second user selection.

In some embodiments, the first user interface comprises a graphical tree of nodes.

In some embodiments, the first user interface comprises a text-based listing of nodes.

Another embodiment includes a system for navigating a large tree of nodes representing components of a computer-aided design drawing. The system includes:
a communication module configured to access data defining a hierarchical tree of nodes, each node representing a corresponding component of a capital project or a subcomponent of a component of a capital project;
a display driver configured to cause display, on a computer monitor, a first user interface comprising a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
a user interface module configured to receive, from a computer user via the first user interface, first user selection of a particular node from the displayed nodes, said particular node being a first selected node, the first selected node being from the first level of nodes;
wherein:
   the display driver is further configured to display, on the computer display in response to said first user selection of said first selected node, a second user interface separate from the first user interface, the second user interface displaying said first selected node in addition to first associated nodes that are associated nodes to the first selected node; and
   the user interface module is further configured to receive, via the first user interface, a second user selection of a second particular node from the tree of nodes, said second particular node being a second selected node from the first level of nodes; and the display driver is further configured to
   display in the second user interface, and in response to said second selection, said second selected node and a second set of sibling nodes of said second selected node while still displaying in the second user interface the first selected node in addition to a parent node of said first selected node, and the first associated nodes of said first selected node.

In some embodiments, the display driver is further configured to display a selection pane displaying a section of the large tree of nodes, the section graphically identifying each node of a plurality of nodes selected by the user, simultaneously with displaying the second user interface displaying said first selected node in addition to first associated nodes that are associated nodes to the first selected node.

In some embodiments, the display driver is further configured to display, as part of the second user interface, a set of graphical elements graphically indicating to the user that the second user interface is distinct from the first user interface.

In some embodiments, the display driver is configured to display a focus button in response to the user placing a graphical pointer over said particular node; and the user interface module is configured to receive user selection of said first selected node via user activation of the focus button.

In some embodiments, the first selected node depends from a parent node via a set of intervening nodes, and the display driver is configured to display, prior to receiving said first user selection of said first selected node, a path window displaying the path from the first selected node to the parent node and all intervening nodes.

Yet another embodiment includes a non-transitory computer-readable medium having computer executable code thereon, the computer executable code, when executed by a computer system, causing the computer system to perform a method. The computer-executable code includes:
code for accessing data defining a hierarchical tree of nodes, each node representing a corresponding component of a capital project or a subcomponent of a component of a capital project;
code for presenting, via a first user interface displayed on a computer display, a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
code for receiving, via the first user interface, a first user selection of a particular node from the displayed nodes, said particular node being a first selected node, the first selected node being from the first level of nodes;
code for displaying, on the computer display in response to said first user selection of said first selected node, a second user interface separate from the first user interface, the second user interface displaying said first selected node in addition to first associated nodes that are associated nodes to the first selected node;
code for receiving, via the first user interface, a second user selection of a second particular node from the tree of nodes, said second particular node being a second selected node from the first level of nodes; and in response to said second selection; and
code for displaying, in the second user interface, said second selected node and a second set of sibling nodes of said second selected node while still displaying in the second user interface the first selected node in addition to a parent node of said first selected node, and the first associated nodes of said first selected node.

Some embodiments further include: code for displaying, on the computer display, a selection pane, the selection pane displaying a section of the large tree of nodes, the section graphically identifying each node of a plurality of nodes selected by the user.

Some embodiments further include: code for displaying, as part of the second user interface, a set of graphical elements graphically indicating to the user that the second user interface is distinct from the first user interface.

Some embodiments further include: code for displaying, prior to receiving said first user selection of said first selected node, a focus button in response to the user placing a graphical pointer over said particular node and, code for causing said generating of said second user interface in response to user activation of said focus button.

In some embodiments, the first selected node depends from a parent node via a set of intervening nodes, and the code further includes: code for displaying, adjacent to the focus button and prior to receiving said first user selection of said first selected node, a path window displaying the path from the first selected node to the parent node and all intervening nodes.

Illustrative embodiments of the invention are implemented as a computer program product having a computer usable medium with computer readable program code thereon. The computer readable code may be read and utilized by a computer system in accordance with conventional processes.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows an embodiment of a prior art tree structure;

FIG. 1B schematically shows an embodiment of a prior art tree structure;

FIG. 2 schematically shows an embodiment of a system;

FIG. 3A is a flowchart of an embodiment of a method;

FIG. 3B schematically illustrates an embodiment of a first user interface and a second user interface;

FIG. 4 schematically illustrates an embodiment of a CAD tree structure;

FIG. 5A schematically illustrates an embodiment of a user interface;

FIG. 5B schematically illustrates an embodiment of a user interface with a path window;

FIG. 5C schematically illustrates an embodiment of a user interface after a first focus selection;

FIG. 5D schematically illustrates an embodiment of a user interface for a subsequent selection;

FIG. 5E schematically illustrates an embodiment of a user interface after a second focus selection;

FIG. 6A schematically illustrates an embodiment of a user interface having a selection pane;

FIG. 6B schematically illustrates an embodiment of a user interface having a selection pane;

FIG. 6C schematically illustrates an embodiment of a user interface having a selection pane;

FIG. 6D schematically illustrates an embodiment of a user interface having a remove button;

FIG. 6E schematically illustrates an embodiment of a user interface subsequent to use of a remove button.

### DESCRIPTION OF ILLUSTRATIVE EMBODIMENTS

Illustrative embodiments address a problem that arises in user interfaces on a computer system.

More specifically, illustrative embodiments provide a computer user interface that address the problem of a user losing track of the user's location within a large tree.

For example, in 3D CAD engineering software, a project (e.g., a factory or other capital project) typically has hundreds or thousands of components. Each component, in turn, may have many sub-components, and each sub-component may have further sub-components. Such components and subcomponents form a hierarchy. Each such component and subcomponent is represented on a hierarchical menu corresponding to the project. The hierarchical menu is a data-centric way of navigating the 3D data.

For example, a factory may have a conveyor system. The conveyor system includes many components, including a conveyor belt, rotors on which the conveyer belt turns, a motor to turn the conveyor belt (or a rotor), and a computer controller to control motion of the conveyor system. Each such component may have one or more subcomponents.

For example, some rotors include a built-in motor, which motor is a subcomponent of the rotor.

A computer controller has several subcomponents, such as a computer processor, a circuit board, a computer memory, input-output circuits, an analog-to-digital converter, a digital-to-analog converter, and electrical connectors. Each subcomponent of the computer controller may itself have subcomponents.

A factory may also have a robot for manipulating production materials. The robot may have several subcomponents, such as a robot arm, a motor to move the robot arm, and a controller. The controller may have several subcomponents, as listed above. The robot arm may also have several subcomponents, such as a plurality of arm segments, joints between arm segments, and a gripper. Each subcomponent of the robot arm may itself have subcomponents. For example, a gripper may have a plurality of fingers, a plurality of joints, and an actuator to move one or more fingers relative to one another.

A factory may also have a pump, for example to supply fuel or raw materials into the factory. The pump may have several subcomponents, such as an inlet valve, an outlet valve, a housing, an impeller, a pump motor, and a pump computer controller. Each subcomponent of the pump may itself have subcomponents. For example, the pump motor may have an electrical cord, and an electrical switch, and an overload fuse.

A text-based hierarchical user interface may display the factory as an indented list, in which each level of indentation signifies a lower level of hierarchical tree. For example:
Factory
   Conveyor System
      Conveyor belt
      Rotor
         Rotor motor
      Computer controller
         Circuit board
         Computer processor
         Computer memory
         Input-output circuits
         Analog-to-digital converter
         Digital-to-analog converter
         Electrical connectors
   Robot
      Robot arm
         Arm segments
         Joints
         Gripper
      Motor to move the robot arm
      Computer controller
         Circuit board
         Computer processor
         Computer memory
         Input-output circuits
         Analog-to-digital converter
         Digital-to-analog converter
         Electrical connectors
      Pump
         Housing;
         Inlet valve
         Outlet valve
         Impeller,
         Pump motor
         Electrical cord
         Electrical switch
         Overload fuse.

These trees can become very large and can be difficult for a user to work with as there can be hundreds of thousands of nodes in the tree.

It can be very easy for the user to lose track of where they are, and it can be equally difficult to manage multiple selection of nodes in the tree when the nodes can be separated in different parts of a very large tree. And due to how traditional extended selection with a mouse works, it can be very easy for a user to accidentally mis-click and lose existing selections across a very large tree.

Illustrative embodiments provide a specialized tree control that allows the user to focus the view to a specific subsection of the tree. This allows the user to focus on a smaller subset of data at one time. Once the user has focused the view to a specific subset, the user can continue to focus the view down even further and can navigate back up because, in some embodiments, a history of the focused subsets is kept.

If a user has selected nodes in the tree and focuses the user's view to a subset, their existing selections are preserved. So, if the user makes a selection in the subset, the user will not lose any of the user's previous selections. This solves the problem of safely making selections across a very large tree.

To help the user navigate in the tree once the user has made one or more selections, the tree can display a list of the user's selections is a focused view which allows the user to quickly navigate the tree to any specific selection and allows the user to remove single selections with a single click.

The tree also has a dynamic search feature that will filer the tree nodes and only display those that meet the user's search input. If the tree is focused to a subset, then the search will only filter that subset. This is an additional way for the user to stay focused in the user's work.

Definitions: As used in this description and the accompanying claims, the following terms shall have the meanings indicated, unless the context otherwise requires.

An “associated node”, with respect to given node on a given branch in a hierarchical tree, is a node on the same branch. For example, but without limiting the scope of the term, an associated node of a given node may be the parent node of the given node, a grandparent node of the given node, or a child node of the given node, or a node below a child node.

A “module” includes computer system hardware under control of computer-executable code which code, when executed by the computer system hardware, causes the computer system to perform the functionality of the associated module. A module may be configured to perform functionality by providing to a computer system computer-executable code which code which code, when executed by the computer system hardware, causes the computer system to perform the functionality.

A “set” includes at least one member.

A “sibling node”, with respect to given node, is a node that is subordinate to the same node (i.e., “parent” node) as the given node.

The term “subordinate,” with respect to a given node in a tree structure, means that the given node is beneath another node in the tree structure. A given node is immediately subordinate to the other node when there are no intervening nodes between the given node and the other node. A given node is indirectly subordinate to the other node when there is at least one intervening node between the given node and the other node.

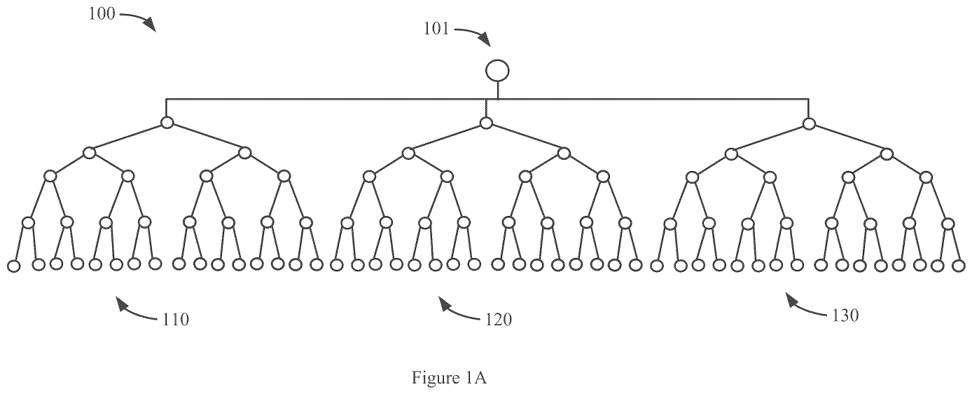

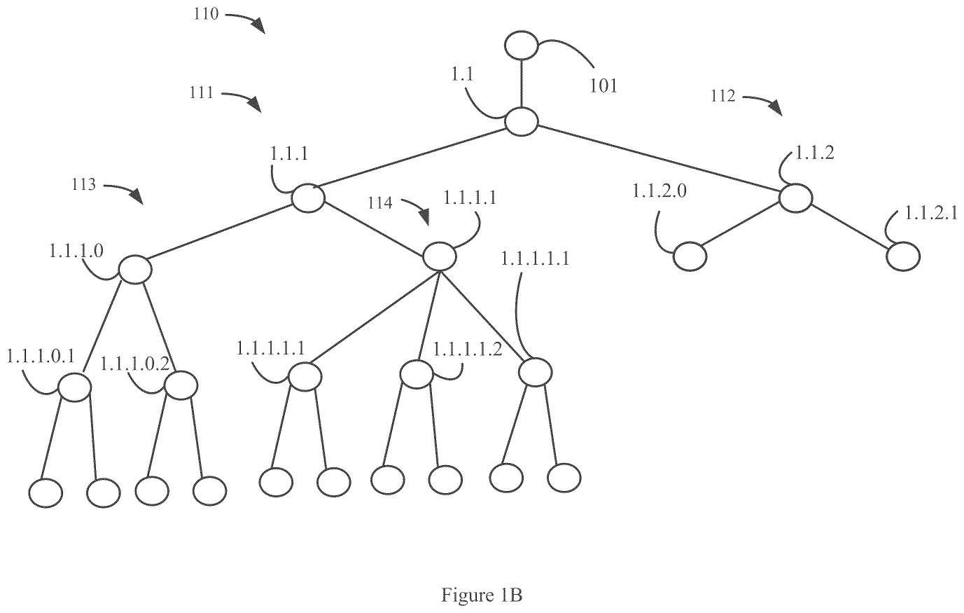

FIG. 1A schematically shows an embodiment of a prior art tree structure 100 having a superior node 101, and a plurality of branches 110, 120, 130, each with a plurality of subordinate branches. In this embodiment, each branch 110, 120 and 130 extends from superior node 101. Each branch 110, 120 and 130 includes a plurality of nodes. Each node may be described as belonging to a corresponding level of the tree structure 100, where the level is defined by a distance from a superior node.

FIG. 1B schematically shows an embodiment of a subordinate branch 110 of the prior art tree structure 100. The subordinate branch 110 depends from node 101 and includes node 1.1. Two branches 111 and 112 extend from node 1.1.

Node 1.1.1 and node 1.1.2 are each subordinate to node 1.1. Two branches 113 and 114 extend from node 1.1.1.

The “level” of a given node, relative to another node, may be defined by the number of nodes intervening between the given node and the other node, where the other node may be referred to as a reference node.

For example, node 1.1.1.0 is on the same level as node 1.1.1.1 because each of node 1.1.1.0 and node 1.1.1.1 is the same distance from node 1.1.1, where node 1.1.1 is the reference node, and where distance is measured by the number of intervening nodes between a node and the reference node. Specifically, node 1.1.1.0 and node 1.1.1.1 are each separated from node 1.1.1 by zero nodes. Similarly, where node 1.1 is specified as the reference node, 1.1.1.0 and node 1.1.1.1 are each separated from node 1.1. by one node (in this case, node 1.1.1).

A node can be on the same level as another node even if those nodes are in different branches, as long as each of those branches extend from a node that the branches have in common. A “common” node, with regard to two branches, is a node from which both branches extend.

For example, node 1.1.1.1 is on the same level as node 1.1.2.0, even though node 1.1.1.1 is on a different branch from node 1.1.1.2. In FIG. 1B, branches 111 and 112 have node 1.1 in common. In this case, node 1.1.1.1 is separated from node 1.1 by one node (in this case, node 1.1.1) and node 1.1.1.2 is separated from node 1.1 by only one node (in this case, node 1.1.2).

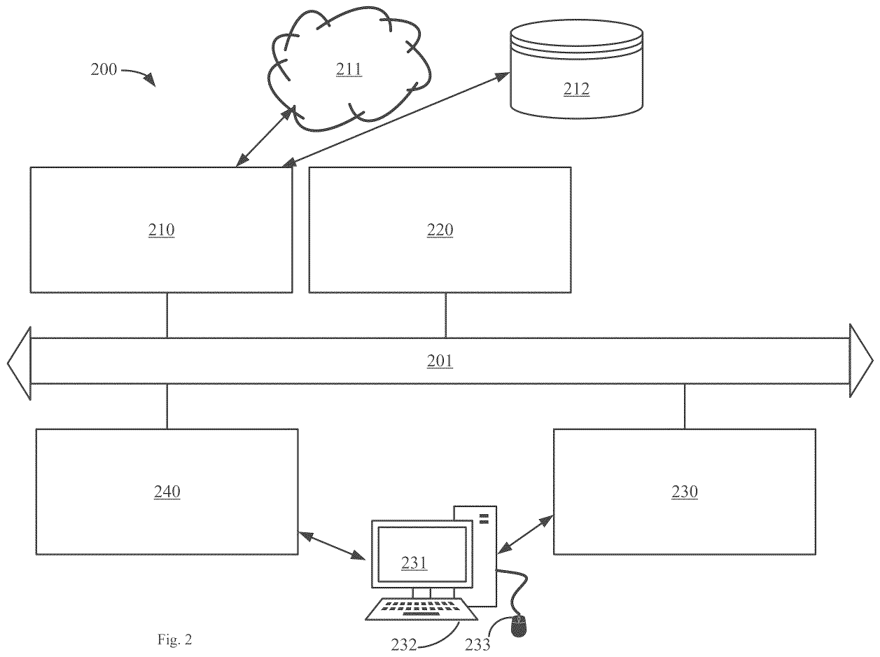

FIG. 2 schematically shows an embodiment of a system 200 comprising a plurality of modules in communication with one another via a bus 201.

The system 200 includes a communications module 210 configured to communicate with electronic devices external to the system, such as a network of computers 211, and/or a database 212. In illustrative embodiments, the communication module 210 is configured to access data defining a hierarchical tree of nodes, each node representing a corresponding component of a capital project or a subcomponent of a component of a capital project. Such data may be stored, for example, in system memory 220, or in a computer network 211, or a database 212, to name but a few examples.

The system 200 includes a memory 220, which may include a non-transitory computer-readable medium. The memory 220 may store data, such as a computer aided-design drawing and a listing of components of a computer aided design drawing, and/or executable computer code.

The system 200 includes a display driver 230 configured to display one or more images, such as a user interface, on a computer display.

The system 200 includes a user interface module 240 configured to receive input from a user. For example, the user interface module may receive user input via a computer keyboard 232 and/or a computer mouse 233, and the user interface module 240 may be configured to display one or more user interfaces on a computer display (or monitor) 231. to name but a few examples.

In illustrative embodiments, modules of the system 200 are configured to cooperate to permit a user to navigate a large tree of nodes representing components of a computer-aided design drawing. Such an illustrative embodiment includes a communication module 210 configured to access data defining a hierarchical tree of nodes, each node representing a corresponding component of a capital project or a subcomponent of a component of a capital project.

The system 200 also includes a display driver module 230 configured to cause display, on a computer monitor, a first user interface comprising a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level.

The system 200 also includes a user interface module 240 configured to receive, from a computer user via the first user interface, first user selection of a particular node from the displayed nodes, said particular node being a first selected node, the first selected node being from the first level of nodes.

In such an illustrative embodiment, the display driver is 230 further configured to display, on the computer display in response to said first user selection of said first selected node, a second user interface separate from the first user interface, the second user interface displaying said first selected node in addition to first associated nodes that are associated nodes to the first selected node; and the user interface module is further configured to receive, via the first user interface, a second user selection of a second particular node from the tree of nodes, said second particular node being a second selected node from the first level of nodes; and the display driver is further configured to display in the second user interface, and in response to said second selection, said second selected node and a second set of sibling nodes of said second selected node while still displaying in the second user interface the first selected node in addition to a parent node of said first selected node, and the first associated nodes of said first selected node.

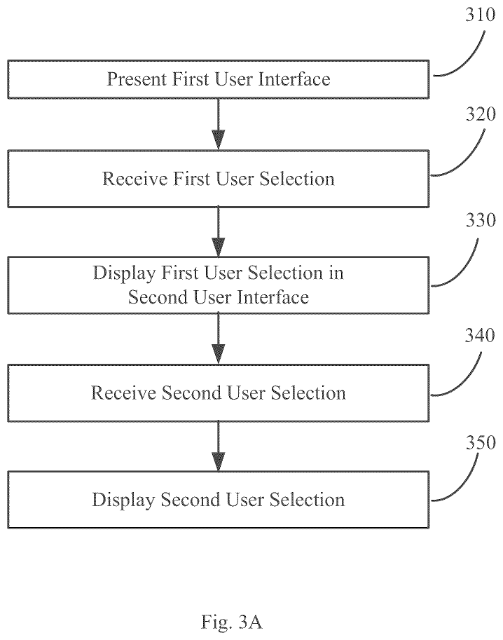

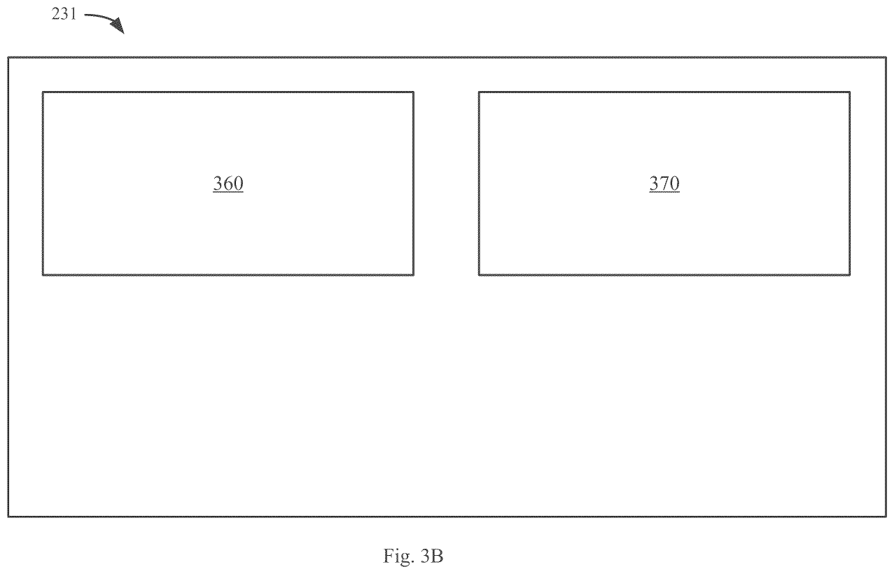

FIG. 3A is a flowchart of an embodiment of a method. FIG. 3B schematically illustrates an embodiment of a first user interface 360 and a second user interface 370 on a computer display 231.

Step 310 includes presenting a user interface on a computer display device, which user interface is configured to enable a user to navigate nodes of a hierarchical tree 100. In illustrative embodiments, step 310 includes presenting, via a first user interface 360 displayed on a computer display, a plurality of displayed nodes. The plurality of displayed nodes includes fewer than all nodes from the tree of nodes, in which at least a first set of the displayed nodes are nodes from a first level in the tree of nodes, and at least a second set of the displayed nodes are nodes from a second level of tree nodes, the second level being lower than the first level. Each node of the second level representing a subcomponent of a component represented by a node of the first level.

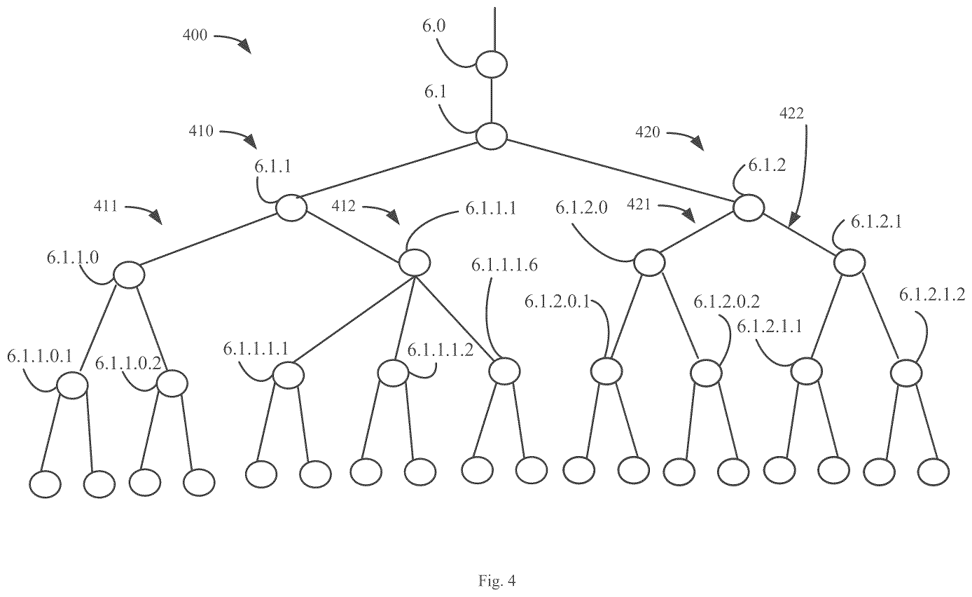

Some embodiments include accessing data defining a hierarchical tree of nodes, each node representing a corresponding component of a capital project or a subcomponent of a component of a capital project. The user interface may be a graphical user interface in which each node graphically represents a corresponding component of a capital project or a subcomponent of a component of a capital project, and in which each node is graphically coupled to at least one other node by a graphical connector, as in FIG. 4, for example.

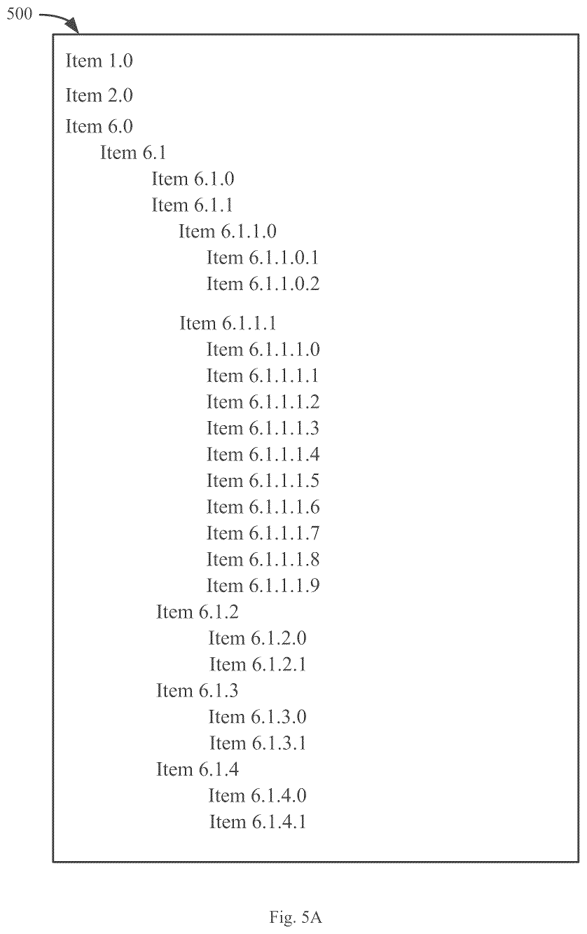

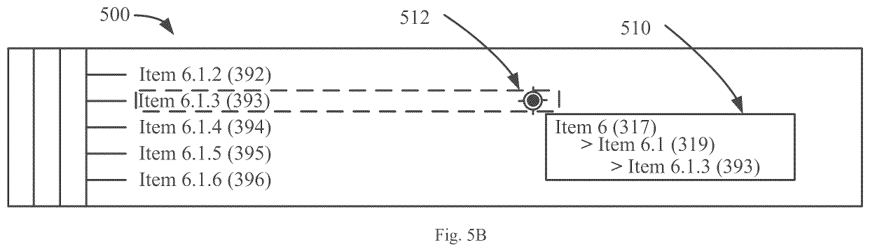

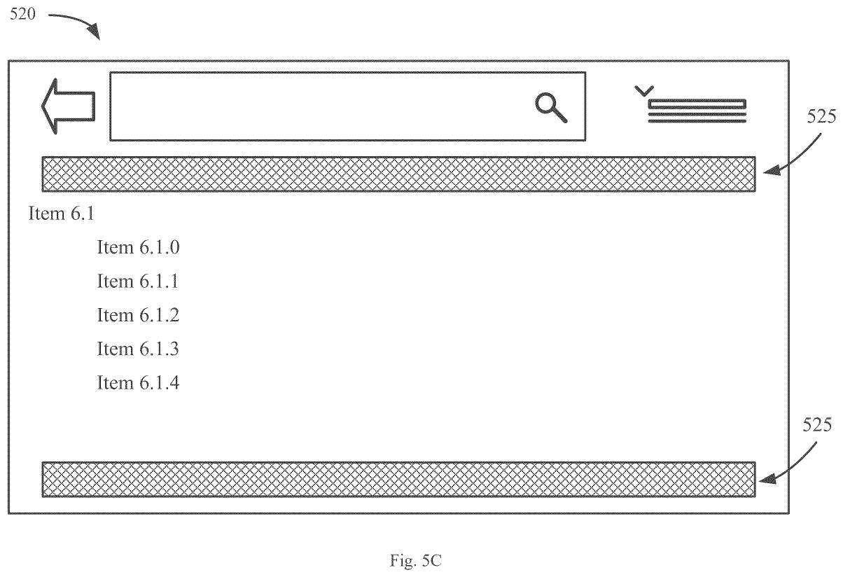

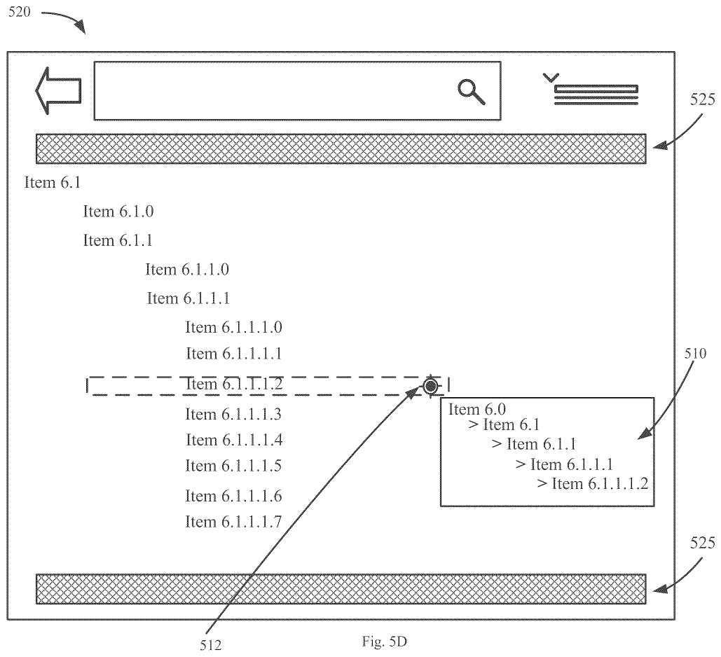

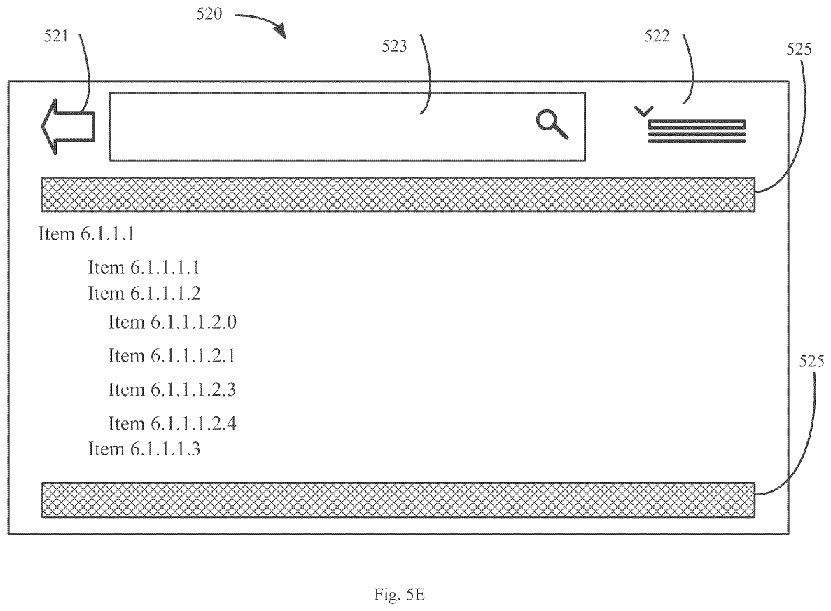

In some embodiments, the user interface presents the nodes as a cascading list of text items, in which each text item represents a corresponding component of a capital project or a subcomponent of a component of a capital project, as in FIG. 5D to name but one example. In such a cascading list, an item that is subordinate to a superior item (e.g., as a subcomponent is subordinate to another component) may be indented relative to the superior item, as in FIG. 5D to name but one example.

In illustrative embodiments, step 310 includes presenting, via a first user interface 360 displayed on a computer display 231, a plurality of displayed nodes. In illustrative embodiments, the displayed nodes include fewer than all nodes from the tree of nodes. At least a first set of the displayed nodes are nodes from a first level in the tree of nodes, and at least a second set of the displayed nodes are nodes from a second level of tree nodes, the second level being lower than the first level. In illustrative embodiments, each node of the second level represents a subcomponent of a component represented by a node of the first level.

Step 320 includes receiving, via the first user interface, a first user selection of a particular node from the displayed nodes, said particular node being a first selected node, the first selected node being from the first level of nodes.

In illustrative embodiments, step 330 includes displaying, on the computer display 231 in response to said first user selection of said first selected node, a second user interface 370 separate from the first user interface 360. In illustrative embodiments, the second user interface displays the first selected node in addition to first associated nodes that are associated nodes to the first selected node.

Step 340 includes receiving, via the first user interface, a second user selection of a second particular node from the tree of nodes. The second particular node is a second selected node from the first level of nodes.

In response to the selection at step 340, step 350 includes displaying, in the second user interface, said second selected node and a second set of sibling nodes of said second selected node while still displaying in the second user interface the first selected node in addition to a parent node of said first selected node, and the first associated nodes of said first selected node

FIG. 4 schematically illustrates a graphical illustration of a tree 400 for purposes of illustrating various embodiments herein. The tree 400 may be a complete tree, or may be a subordinate branch of a larger tree. In illustrative embodiments, the tree 400 may include a hierarchical tree of nodes, each node representing a corresponding component of a capital project or a subcomponent of a component of a capital project.

Tree 400 has a top node 6.1. Two subordinate branches 410 and 420 extend from top node 6.1. Branch 410 begins with node 6.1.1, which is subordinate to top node 6.1, and branch 420 node 6.1.2, which is subordinate to top node 6.1. Node 6.1.1 is on the same level as node 6.1.2, although those nodes are in different branches with respect to node 6.1.

Two subordinate branches 411 and 412 extend from node 6.1.1.

Branch 411 begins with node 6.1.1.0, and branch 412 begins with node 6.1.1.1.

Node 6.1.1.0 is on the same level as node 6.1.1.1, although those nodes are in different branches with respect to node 6.1.1.

Two subordinate branches 421 and 422 extend from node 6.1.2.

Branch 421 begins with node 6.1.2.0, and branch 422 begins with node 6.1.2.1.

Node 6.1.2.0 is on the same level as node 6.1.2.1, although those nodes are in different branches with respect to node 6.1.2.

Nodes 6.1.1.0, 6.1.1.1, 6.1.2.0 and 6.1.2.1 are all on the same level, and each has subordinate branches.

Likewise, nodes 6.1.1.0.1, 6.1.1.0.2, 6.1.1.1.1, 6.1.1.1.2, 6.1.1.1.6, 6.1.2.0.1, 6.1.2.0.2, 6.1.2.1.1 and 6.1.2.1.2 are all on the same level, and each has subordinate branches.

FIG. 5A schematically illustrates an embodiment of a computer user interface 500 displaying at least a portion of a large tree in which each node of the tree is referred-to as an “item.” In this illustrative example, the tree 400 of FIG. 4 may be considered to be a sub-portion of the tree represented in FIG. 5A.

Some embodiments include a path window 510 that is displayed in response to a user selecting, or hovering over, a specific item in the tree 500. In some embodiments, when user hovers a mouse pointer over a tree node that is not at the root level, a focus element 512 appears in the user interface. In some embodiments, the focus element 512 is accompanied by a path window 510 showing the full hierarchical path of the node. If the user clicks on the focus element 512, the tree view will be focused to the item—if it has children—or the item's parent node.

For example, FIG. 5B schematically shows a path window 510 corresponding to specific Item 6.1.3. The path window 510 recites the path from that specific item (Item 6.1.3.) to its parent (Item 6.1) and its grandparent (item 6.0). The path window 510 displays information that informs the user about where the specific item (Item 6.1.3) is within the context of the tree 400, and thereby helps keep the user oriented to the tree 400 even when much or most of the tree 400 is not displayed on screen.

In illustrative embodiments, the path window 510 includes a focus element 512, which focus element 512 is in addition to the displayed item to which is corresponds.

When the user selects (e.g., clicks on) the focus element 512 (which may be a button for example), the user interface focuses to the specific item and its siblings (i.e., items that are on the same level of the specific item and that are subordinate to the specific item's parent). In some embodiments, the focus also includes the parent item of the specific item.

For example, if the user selects the focus element 512 in FIG. 5B, a second user interface 520 (which may referred-to as a “focus window” and which is an embodiment of second user interface 370) (FIG. 5C) displays the associated specific item (Item 6.1.3) in the context of its parent item (Item 6.1) along with its sibling items (Item 6.1.0; Item 6.1.1; Item 6.1.2; and Item 6.1.4).

Illustrative embodiments allow the user to select another item (from the second user interface 370), which may be referred-to as an additional item, without losing simultaneous display of the user's previous selection or selections of items from the tree. The additional item may be from the same level as the specific item, or from a level below the level of the specific item, or from a level above the level of the specific item.

FIG. 5D schematically illustrates a user interface in which the user has specified an additional item (Item 6.1.1.1.2) which is from a different branch than the first item (Item 6.1.3). FIG. 5D also includes a second path window 510 with a second focus element 512.

When the user selects (e.g., clicks on) the second focus element 512 (which may be a button for example), the user interface focuses to the specific item (in this example, Item 6.1.1.1.2) and its siblings, as schematically illustrated in FIG. 5E, for example. In some embodiments, the focus also includes the parent item (in this example, Item 6.1.1.1) item of the specific item. In some embodiments, the focus also includes the children items (in this example, Item 6.1.1.1.2.0; Item 6.1.1.1.2.1; Item 6.1.1.1.2.3; Item 6.1.1.1.2.4) of the specific item.

In illustrative embodiments, the focus window 520 may also include a selection pane toggle device 522 (e.g., an icon) that when activated causes the selection pane 622 to be displayed, and when not activated causes the selection pane 622 to not be displayed. Activating (e.g., clicking on) the toggle device 522 toggles the visibility of the selection pane 622.

In illustrative embodiments, the focus window 520 may also include a search box 523 that allows a user to input a search term to identify items within the tree.

In illustrative embodiments, the focus window 520 may also include one or more graphical elements 525 that graphically signal to the user that the focus window 520 is a subset of the tree created by selecting one or more elements of the tree, as described above. In illustrative embodiments, the one or more graphical elements 525 are in addition to borders of a window in which the user interface is displayed, and in addition to elements of such a window. In some embodiments, a focus window shows a graphical element 525 at the tope and/or bottom of the focus window to denote that the focus window 520 is displaying a subset of the full tree. Alternatively, or in addition, some embodiments display a text label indicating that the focus window 520 is displaying a subset of the full tree. The user can continue to work in the subset displayed in the focus window 520, or may narrow the focus further (e.g., while remaining within the focus window 520) by clicking a focus element 512 on or associated with other child nodes displayed in the focus window 512.

In illustrative embodiments, the focus window 520 may also include a back button 521 (which may take the form of a back arrow), that allows the user to undo the user's immediately preceding act. FIG. 5E schematically illustrates a user interface 520 with a back button 521. To that end, some embodiments keep a history of the user focus actions, so that the user can navigate backward through the focused views using the back button 521.

FIG. 5E schematically illustrates user interface 520 after the user has focused the user interface of FIG. 5D by activating button 512 to select and focus the user interface to expand item 6.1.1.1.2. After activating back button 521, the user interface from FIG. 5E reverts to the user interface in FIG. 5D.

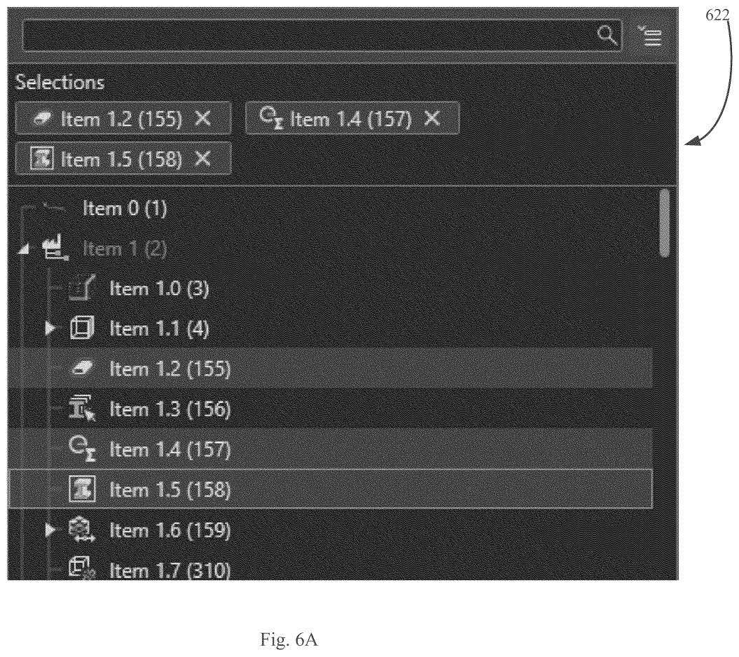

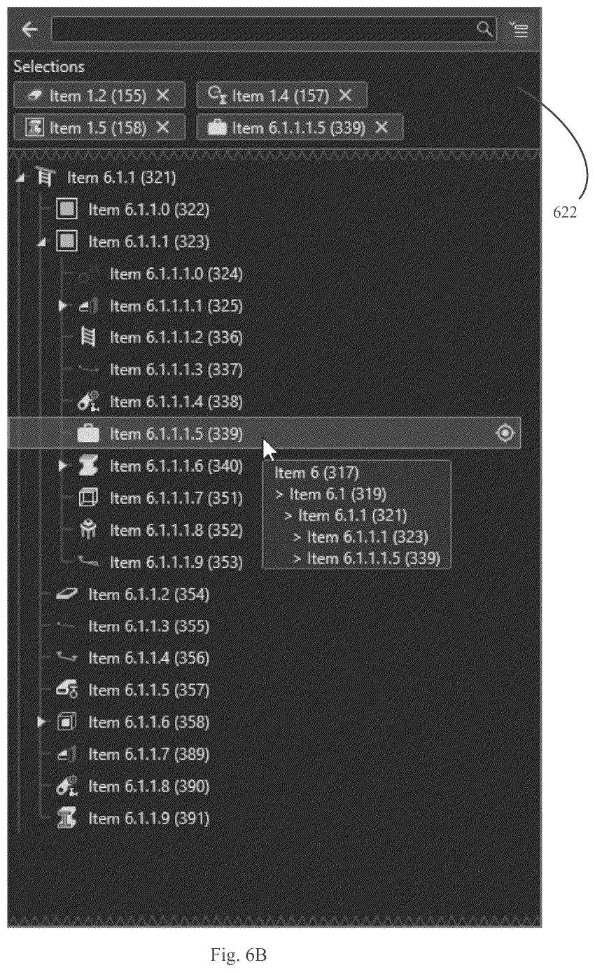

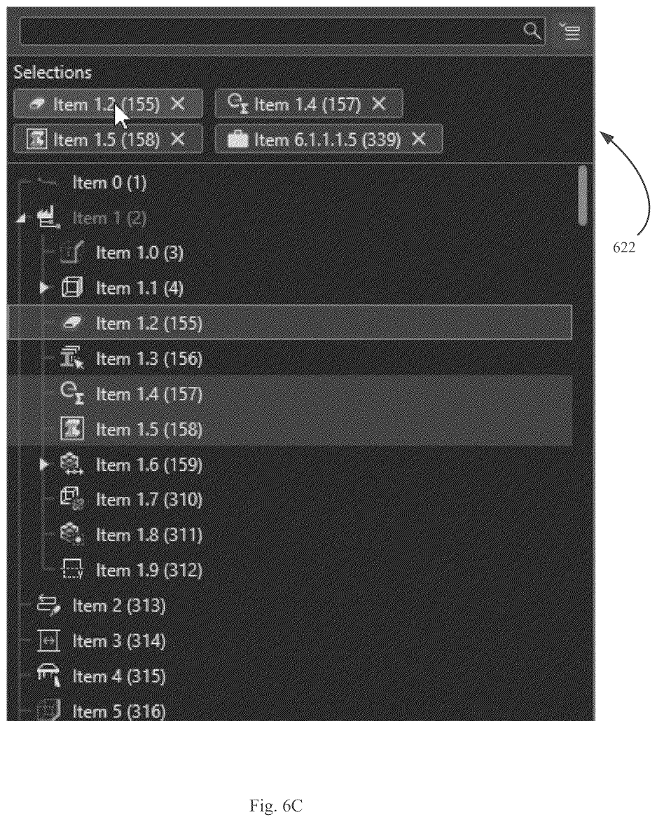

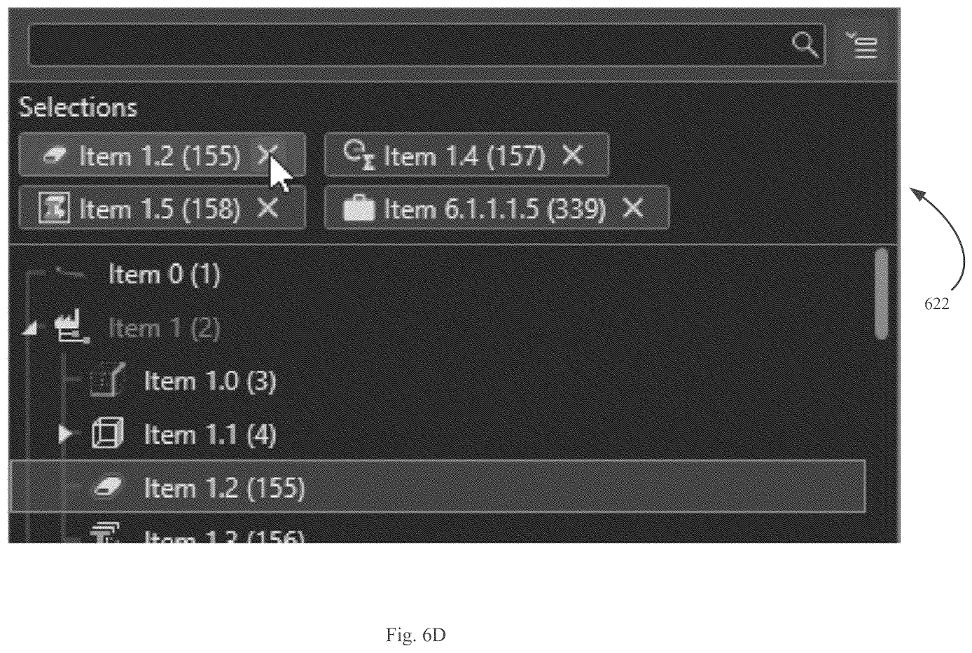

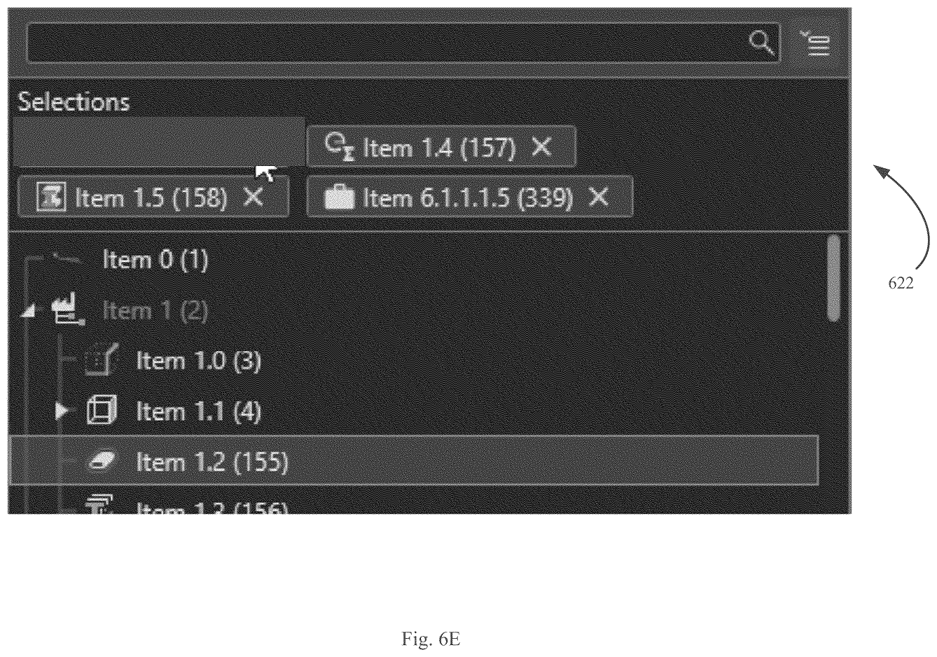

FIG. 6A schematically illustrates an embodiment of a user interface having a selection pane 622. As illustrated in FIG. 6A, the user has made three selection (Item 1.2, Item 1.4 and Item 1.5) . If the user desired to focus into another part of the tree, the user can, in some embodiments, left-click, CTRL+left-click, and SHIFT+left-click to make additional selections without losing the user's previous selections.

FIG. 6B schematically illustrates an embodiment of a user interface having a selection pane 622. The selection pane 622 displays several nodes that have been selected by a user. One of those nodes [“Item 6.1.1.1.5 (339)”] is also displayed in the tree of nodes, and is highlighted to indicates that that node has been selected and that it is also displayed in the selection pane 622. In FIG. 6B, as the user select a node [“Item 6.1.1.1.5 (339)”], the system and methods add that node to the selection pane 622. A user can easily navigate to a previous selection by clicking on the icon for that selection within the selection pane 622.

FIG. 6C schematically illustrates an embodiment of a user interface having a selection pane in which several nodes are listed in the selection pane 122 and are also displayed in text format in the second user interface. The nodes displayed in text format are also highlighted.

FIG. 6D schematically illustrates an embodiment of a user interface having a remove button 623. FIG. 6E schematically illustrates an embodiment of a user interface subsequent to use of a remove button. Specifically, the user interface of FIG. 6D includes an icon for “Item 1.2 (155).” FIG. 6E schematically illustrates that user interface after the user uses the remove button to remove “Item 1.2 (155)” from the selection pane 622, and so FIG. 6E does not include “Item 1.2 (155)” in the selection pane 622, although “Item 1.2 (155)” still appears in the second graphical user interface.

Various embodiments may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

Without limitation, potential subject matter that may be claimed (prefaced with the letter “P” so as to avoid confusion with the actual claims presented below) includes:
P1. A method for navigating a large tree of nodes representing components of a computer-aided design drawing, the tree having a plurality of nodes across a plurality of levels, the method comprising:
   accessing data defining a hierarchical tree of nodes, each node representing a corresponding component of a capital project or a subcomponent of a component of a capital project;
   presenting, via a first user interface displayed on a computer display, a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
   receiving, via the first user interface, a first user selection of a particular node from the displayed nodes, said particular node being a first selected node, the first selected node being from the first level of nodes;
   displaying, on the computer display in response to said first user selection of said first selected node, a second user interface separate from the first user interface, the second user interface displaying said first selected node in addition to first associated nodes that are associated nodes to the first selected node;
   receiving, via the first user interface, a second user selection of a second particular node from the tree of nodes, said second particular node being a second selected node from the first level of nodes; and in response to said second selection; and
   displaying, in the second user interface, said second selected node and a second set of sibling nodes of said second selected node while still displaying in the second user interface the first selected node in addition to a parent node of said first selected node, and the first associated nodes of said first selected node.
P2. The method of P1, further comprising:
   displaying, on the computer display, a selection pane, the selection pane displaying a section of the large tree of nodes, the section graphically identifying each node of a plurality of nodes selected by the user.
P3. The method of P2, wherein graphically identifying each node of the plurality of nodes selected by the user comprises:
   highlighting each node of the plurality of nodes selected by the user.
P4. The method of any of P1-P3, further comprising:
   providing a selection pane toggle device that, in a first state causes the selection pane to be displayed, and in an alternate, second state cause the selection pane to not be displayed.
P5. The method of any of P1-P4, further comprising:
   displaying, as part of the second user interface, a set of graphical elements graphically indicating to the user that the second user interface is distinct from the first user interface.
P6. the method of any of P1-p5, further comprising:
   prior to receiving said first user selection of said first selected node:
   displaying a focus button in response to the user placing a graphical pointer over said particular node and, in response to user activation of said focus button:
   causing said generating of said second user interface.
P7. The method of P6, wherein the first selected node depends from a parent node via a set of intervening nodes, and the method further comprises:
   prior to receiving said first user selection of said first selected node:
   displaying, adjacent to the focus button, a path window displaying the path from the first selected node to the parent node and all intervening nodes.
P8. The method of any of P1-P7, further comprising:
   displaying a back button configured to revert the user interface to a previous state after receiving said second user selection, said previous state displaying the user interface as it was prior to receiving said second user selection.
P9. The method of any of P1-P8, wherein the first user interface comprises a graphical tree of nodes.
P10. The method of any of P1-P9, wherein the first user interface comprises a text-based listing of nodes.
P11. A system for navigating a large tree of nodes representing components of a computer-aided design drawing, the system comprising:
   a communication module configured to access data defining a hierarchical tree of nodes, each node representing a corresponding component of a capital project or a subcomponent of a component of a capital project;
   a display driver configured to cause display, on a computer monitor, a first user interface comprising a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
   a user interface module configured to receive, from a computer user via the first user interface, first user selection of a particular node from the displayed nodes, said particular node being a first selected node, the first selected node being from the first level of nodes;
   wherein:
      the display driver is further configured to display, on the computer display in response to said first user selection of said first selected node, a second user interface separate from the first user interface, the second user interface displaying said first selected node in addition to first associated nodes that are associated nodes to the first selected node; and
      the user interface module is further configured to receive, via the first user interface, a second user selection of a second particular node from the tree of nodes, said second particular node being a second selected node from the first level of nodes; and the display driver is further configured to
      display in the second user interface, and in response to said second selection, said second selected node and a second set of sibling nodes of said second selected node while still displaying in the second user interface the first selected node in addition to a parent node of said first selected node, and the first associated nodes of said first selected node.
P12. The system of P11, wherein the display driver is further configured to display a selection pane displaying a section of the large tree of nodes, the section graphically identifying each node of a plurality of nodes selected by the user, simultaneously with displaying the second user interface displaying said first selected node in addition to first associated nodes that are associated nodes to the first selected node.
P13. The system of any of P11-P12, wherein the display driver is further configured to display, as part of the second user interface, a set of graphical elements graphically indicating to the user that the second user interface is distinct from the first user interface.
P14. The system of any of P11-P13, wherein:
   the display driver is configured to display a focus button in response to the user placing a graphical pointer over said particular node; and
   the user interface module is configured to receive user selection of said first selected node via user activation of the focus button.
P15. The system of any of P11-P14, wherein the first selected node depends from a parent node via a set of intervening nodes, and the display driver is configured to display, prior to receiving said first user selection of said first selected node, a path window displaying the path from the first selected node to the parent node and all intervening nodes.
P16. A non-transitory computer-readable medium having computer executable code thereon, the computer executable code, when executed by a computer system, causing the computer system to perform a method, the code comprising:
   code for accessing data defining a hierarchical tree of nodes, each node representing a corresponding component of a capital project or a subcomponent of a component of a capital project;
   code for presenting, via a first user interface displayed on a computer display, a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
   code for receiving, via the first user interface, a first user selection of a particular node from the displayed nodes, said particular node being a first selected node, the first selected node being from the first level of nodes;
   code for displaying, on the computer display in response to said first user selection of said first selected node, a second user interface separate from the first user interface, the second user interface displaying said first selected node in addition to first associated nodes that are associated nodes to the first selected node;
   code for receiving, via the first user interface, a second user selection of a second particular node from the tree of nodes, said second particular node being a second selected node from the first level of nodes; and in response to said second selection; and
   code for displaying, in the second user interface, said second selected node and a second set of sibling nodes of said second selected node while still displaying in the second user interface the first selected node in addition to a parent node of said first selected node, and the first associated nodes of said first selected node.
P17. The non-transitory computer-readable medium of P16, further comprising:
   code for displaying, on the computer display, a selection pane, the selection pane displaying a section of the large tree of nodes, the section graphically identifying each node of a plurality of nodes selected by the user.
P18. The non-transitory computer-readable medium of any of P16-P17, further comprising:
   code for displaying, as part of the second user interface, a set of graphical elements graphically indicating to the user that the second user interface is distinct from the first user interface.
P19. The non-transitory computer-readable medium of any of P16-P18, further comprising:
   code for displaying, prior to receiving said first user selection of said first selected node, a focus button in response to the user placing a graphical pointer over said particular node and,
   code for causing said generating of said second user interface in response to user activation of said focus button.
P20. The non-transitory computer-readable medium of any of P16-P19, wherein the first selected node depends from a parent node via a set of intervening nodes, and the code further comprises:
   code for displaying, adjacent to the focus button and prior to receiving said first user selection of said first selected node, a path window displaying the path from the first selected node to the parent node and all intervening nodes.

Various embodiments of this disclosure may be implemented at least in part in any conventional computer programming language. For example, some embodiments may be implemented in a procedural programming language (e.g., “C”), or in an object-oriented programming language (e.g., “C++”), or in Python, R, Java, LISP or Prolog. Other embodiments of this disclosure may be implemented as preprogrammed hardware elements (e.g., application specific integrated circuits, FPGAs, and digital signal processors), or other related components.

In an alternative embodiment, the disclosed apparatus and methods may be implemented as a computer program product for use with a computer system. Such implementation may include a series of computer instructions fixed either on a tangible medium, such as a non-transitory computer readable medium (e.g., a diskette, CD-ROM, ROM, FLASH memory, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink wrapped software), preloaded with a computer system (e.g., on system ROM or fixed disk), or distributed from a server or electronic bulletin board over the network (e.g., the Internet or World Wide Web). Of course, some embodiments of this disclosure may be implemented as a combination of both software (e.g., a computer program product) and hardware. Still other embodiments of this disclosure are implemented as entirely hardware, or entirely software.

Computer program logic implementing all or part of the functionality previously described herein may be executed at different times on a single processor (e.g., concurrently) or may be executed at the same or different times on multiple processors and may run under a single operating system process/thread or under different operating system processes/threads. Thus, the term “computer process” refers generally to the execution of a set of computer program instructions regardless of whether different computer processes are executed on the same or different processors and regardless of whether different computer processes run under the same operating system process/thread or different operating system processes/threads.

The embodiments of the invention described above are intended to be merely exemplary; numerous variations and modifications will be apparent to those skilled in the art. Such variations and modifications are intended to be within the scope of the present invention as defined by any of the appended claims.

What is claimed is:

1. A method for navigating a large tree of nodes representing components of a computer-aided design drawing, the tree having a plurality of nodes across a plurality of levels, the method comprising:
accessing data defining a hierarchical tree of nodes, each node representing a corresponding component of a capital project or a subcomponent of a component of a capital project;
presenting, via a first user interface displayed on a computer display, a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
receiving, via the first user interface, a first user selection of a particular node from the displayed nodes, said particular node being a first selected node, the first selected node being from the first level of nodes;
displaying, on the computer display in response to said first user selection of said first selected node, a second user interface separate from the first user interface, the second user interface displaying said first selected node in addition to first associated nodes that are associated nodes to the first selected node;
receiving, via the first user interface, a second user selection of a second particular node from the tree of nodes, said second particular node being a second selected node from the first level of nodes; and in response to said second selection; and
displaying, in the second user interface, said second selected node and a second set of sibling nodes of said second selected node while still displaying in the second user interface the first selected node in addition to a parent node of said first selected node, and the first associated nodes of said first selected node.

2. The method of claim 1, further comprising:
displaying, on the computer display, a selection pane, the selection pane displaying a section of the large tree of nodes, the section graphically identifying each node of a plurality of nodes selected by the user.

3. The method of claim 2, wherein graphically identifying each node of the plurality of nodes selected by the user comprises:
highlighting each node of the plurality of nodes selected by the user.

4. The method of claim 1, further comprising:
providing a selection pane toggle device that, in a first state causes the selection pane to be displayed, and in an alternate, second state cause the selection pane to not be displayed.

5. The method of claim 1, further comprising:
displaying, as part of the second user interface, a set of graphical elements graphically indicating to the user that the second user interface is distinct from the first user interface.

6. The method of claim 1, further comprising:
prior to receiving said first user selection of said first selected node:
displaying a focus button in response to the user placing a graphical pointer over said particular node and, in response to user activation of said focus button:
causing said generating of said second user interface.

7. The method of claim 6, wherein the first selected node depends from a parent node via a set of intervening nodes, and the method further comprises:
prior to receiving said first user selection of said first selected node:
displaying, adjacent to the focus button, a path window displaying the path from the first selected node to the parent node and all intervening nodes.

8. The method of claim 1, further comprising:
displaying a back button configured to revert the user interface to a previous state after receiving said second user selection, said previous state displaying the user interface as it was prior to receiving said second user selection.

9. The method of claim 1, wherein the first user interface comprises a graphical tree of nodes.

10. The method of claim 1, wherein the first user interface comprises a text-based listing of nodes.

11. A system for navigating a large tree of nodes representing components of a computer-aided design drawing, the system comprising:
a communication module configured to access data defining a hierarchical tree of nodes, each node representing a corresponding component of a capital project or a subcomponent of a component of a capital project;
a display driver configured to cause display, on a computer monitor, a first user interface comprising a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
a user interface module configured to receive, from a computer user via the first user interface, first user selection of a particular node from the displayed nodes, said particular node being a first selected node, the first selected node being from the first level of nodes;
wherein:
the display driver is further configured to display, on the computer display in response to said first user selection of said first selected node, a second user interface separate from the first user interface, the second user interface displaying said first selected node in addition to first associated nodes that are associated nodes to the first selected node; and
the user interface module is further configured to receive, via the first user interface, a second user selection of a second particular node from the tree of nodes, said second particular node being a second selected node from the first level of nodes; and the display driver is further configured to
display in the second user interface, and in response to said second selection, said second selected node and a second set of sibling nodes of said second selected node while still displaying in the second user interface the first selected node in addition to a parent node of said first selected node, and the first associated nodes of said first selected node.

12. The system of claim 11, wherein the display driver is further configured to display a selection pane displaying a section of the large tree of nodes, the section graphically identifying each node of a plurality of nodes selected by the user, simultaneously with displaying the second user interface displaying said first selected node in addition to first associated nodes that are associated nodes to the first selected node.

13. The system of claim 11, wherein the display driver is further configured to display, as part of the second user interface, a set of graphical elements graphically indicating to the user that the second user interface is distinct from the first user interface.

14. The system of claim 11, wherein:
the display driver is configured to display a focus button in response to the user placing a graphical pointer over said particular node; and
the user interface module is configured to receive user selection of said first selected node via user activation of the focus button.

15. The system of claim 11, wherein the first selected node depends from a parent node via a set of intervening nodes, and the display driver is configured to display, prior to receiving said first user selection of said first selected node, a path window displaying the path from the first selected node to the parent node and all intervening nodes.

16. A non-transitory computer-readable medium having computer executable code thereon, the computer executable code, when executed by a computer system, causing the computer system to perform a method, the code comprising:
code for accessing data defining a hierarchical tree of nodes, each node representing a corresponding component of a capital project or a subcomponent of a component of a capital project;
code for presenting, via a first user interface displayed on a computer display, a plurality of displayed nodes, the displayed nodes comprising fewer than all nodes from the tree of nodes, at least a first set of the displayed nodes being nodes from a first level in the tree of nodes, and at least a second set of the displayed nodes being nodes from a second level of tree nodes, the second level being lower than the first level, each node of the second level representing a subcomponent of a component represented by a node of the first level;
code for receiving, via the first user interface, a first user selection of a particular node from the displayed nodes, said particular node being a first selected node, the first selected node being from the first level of nodes;
code for displaying, on the computer display in response to said first user selection of said first selected node, a second user interface separate from the first user interface, the second user interface displaying said first selected node in addition to first associated nodes that are associated nodes to the first selected node;
code for receiving, via the first user interface, a second user selection of a second particular node from the tree of nodes, said second particular node being a second selected node from the first level of nodes; and in response to said second selection; and
code for displaying, in the second user interface, said second selected node and a second set of sibling nodes of said second selected node while still displaying in the second user interface the first selected node in addition to a parent node of said first selected node, and the first associated nodes of said first selected node.

17. The non-transitory computer-readable medium of claim 16, further comprising:
code for displaying, on the computer display, a selection pane, the selection pane displaying a section of the large tree of nodes, the section graphically identifying each node of a plurality of nodes selected by the user.

18. The non-transitory computer-readable medium of claim 16, further comprising:
code for displaying, as part of the second user interface, a set of graphical elements graphically indicating to the user that the second user interface is distinct from the first user interface.

19. The non-transitory computer-readable medium of claim 16, further comprising:
code for displaying, prior to receiving said first user selection of said first selected node, a focus button in response to the user placing a graphical pointer over said particular node and,
code for causing said generating of said second user interface in response to user activation of said focus button.

20. The non-transitory computer-readable medium of claim 16, wherein the first selected node depends from a parent node via a set of intervening nodes, and the code further comprises:
code for displaying, adjacent to the focus button and prior to receiving said first user selection of said first selected node, a path window displaying the path from the first selected node to the parent node and all intervening nodes.
